(19) United States
(12) Patent Application Publication
(10) Pub. No.: US 2019/0123278 A1
(43) Pub. Date: Apr. 25, 2019

(54) STRIPPING METHOD FOR A FLEXIBLE SUBSTRATE AND FLEXIBLE SUBSTRATE

(71) Applicant: WUHAN CHINA STAR OPTOELECTRONICS DISPLAY TECHNOLOGY CO., LTD., Wuhan, Hubei (CN)

(72) Inventors: Xin ZOU, Shenzhen, Guangdong (CN); Hsiang-lun HSU, Shenzhen, Guangdong (CN)

(21) Appl. No.: 15/744,789

(22) PCT Filed: Dec. 20, 2017
(86) PCT No.: PCT/CN2017/117342

§ 371 Date: Jan. 13, 2018

(30) Foreign Application Priority Data
Oct. 23, 2017 (CN) 201711006653.0

(51) Int. Cl. H01L 51/00; H01L 51/56; H01L 27/32

(52) U.S. Cl. CPC H01L 51/003; H01L 27/3244; H01L 51/56; H01L 51/0097

(57) ABSTRACT

A stripping method for a flexible substrate and a flexible substrate are provided. The stripping method for a flexible substrate includes: forming an optical anti-reflection layer on a first surface of a carrier substrate; forming a photosensitive layer on a second surface of the carrier substrate, the first surface opposite to the second surface; forming a flexible substrate on the photosensitive layer; and illuminating the first surface of the carrier substrate to strip the flexible substrate from the carrier substrate. The optical anti-reflection layer of the disclosure can improve the transmissivity of the incident light and reduce the reflectivity of the incident light, so the light energy utilization rate could be improved. Furthermore, the laser damage is also reduced due to the reduce of the reflected light energy.

### RELATED APPLICATIONS

The present application is a National Phase of International Application Number PCT/CN2017/117342, filed Dec. 20, 2017, and claims the priority of China Application No. 201711006653.0, filed Oct. 23, 2017.

### FIELD OF THE DISCLOSURE

The disclosure relates to a display technical field, and more particularly to a temperature compensation circuit and method for a stripping method for a flexible substrate and a flexible substrate.

### BACKGROUND

Organic Light-Emitting Diode (OLED) display technology has been widely concerned with the advantages of self-luminous, wide viewing angle, fast response, low power consumption and so on. In recent years, the display technology of flexible OLED organic light-emitting devices has been rapidly developed, compared with the traditional glass rigid display device, the flexible display device has a series of advantages such as impact resistance, strong shock resistance, light weight, small size and even wearable.

Flexible substrates are currently widely used in flexible display devices, they have good bending properties, but the problem is too soft, a variety of film forming process is a challenge. Therefore, in the manufacturing process of a flexible substrate, a carrier substrate with good surface flatness and excellent rigidity is generally required. After the manufacture of the flexible substrate is completed, the flexible substrate needs to be stripped from the carrier substrate. Therefore, stripping the flexible substrate from the carrier substrate effectively is one of the key technologies for manufacturing flexible display devices.

High-energy laser irradiation is widely used in stripping method currently, that is, the interface between the flexible substrate and the carrier substrate is applied high-energy laser to burn the polymer of the interface so that the flexible substrate could separate from the carrier substrate. However, air and glass are two completely different media with large differences in refractive index, the refractive index n1 of air can be approximately considered as 1, the refractive index n2 of glass is between 1.5˜1.7. The laser will reflect approximately 6% of the light vertically from the air to the glass, which is not only wasting light energy, but also reflecting the light into the laser device will damage the internal components.

### SUMMARY

A technical problem to be solved by the disclosure is to provide a stripping method for a flexible substrate and a flexible substrate, so the reflectivity of the incident light could be reduced, and the light energy utilization rate could be improved.

To achieve the above object, according to one aspect, the embodiment of the disclosure provides a stripping method for a flexible substrate, including:
performing physical vapor deposition, chemical liquid deposition or chemical vapor deposition on a first surface of a carrier substrate to form an optical anti-reflection layer,
forming a photosensitive layer on a second surface of the carrier substrate, the first surface opposite to the second surface;
forming a flexible substrate on the photosensitive layer; and
illuminating the first surface of the carrier substrate with a laser to strip the flexible substrate from the carrier substrate.

To achieve the above object, according to another aspect, the embodiment of the disclosure provides a stripping method for a flexible substrate, including: forming an optical anti-reflection layer on a first surface of a carrier substrate; forming a photosensitive layer on a second surface of the carrier substrate, the first surface opposite to the second surface; forming a flexible substrate on the photosensitive layer, and illuminating the first surface of the carrier substrate to strip the flexible substrate from the carrier substrate.

To achieve the above object, according to another aspect, the embodiment of the disclosure provides a flexible substrate, wherein the flexible substrate is manufactured by the following steps, including:
forming an optical anti-reflection layer on a first surface of a carrier substrate;
forming a photosensitive layer on a second surface of the carrier substrate, the first surface opposite to the second surface;
forming a flexible substrate on the photosensitive layer; and
illuminating the first surface of the carrier substrate to strip the flexible substrate from the carrier substrate.

The beneficial effects of the disclosure are as follows, compare with the conventional technology, a stripping method for a flexible substrate provided by the disclosure includes: forming an optical anti-reflection layer on a first surface of a carrier substrate; forming a photosensitive layer on a second surface of the carrier substrate, the first surface opposite to the second surface; forming a flexible substrate on the photosensitive layer and illuminating the first surface of the carrier substrate to strip the flexible substrate from the carrier substrate. The optical anti-reflection layer of the disclosure can improve the transmissivity of the incident light and reduce the reflectivity of the incident light, so the light energy utilization rate could be improved. Furthermore, the laser damage is also reduced due to the reduce of the reflected light energy.

### BRIEF DESCRIPTION OF THE DRAWINGS

FIG. 1 is a flow chart diagram of a stripping method for a flexible substrate according to an embodiment of the disclosure;

FIG. 2 is a structural schematic view of forming an optical anti-reflection layer on a first surface of a carrier substrate according to an embodiment of the disclosure;

FIG. 3 is a structural schematic view of forming a photosensitive layer on a second surface of a carrier substrate according to an embodiment of the disclosure;

FIG. 4 is a structural schematic view of forming a flexible substrate on a photosensitive layer according to an embodiment of the disclosure;

FIG. 5 is a structural schematic view of illuminating a first surface of a carrier substrate according to an embodiment of the disclosure;

FIG. 6 is a structural schematic view of stripping a flexible substrate from a carrier substrate according to an embodiment of the disclosure.

### DETAILED DESCRIPTION OF PREFERRED EMBODIMENTS

In order to facilitate understanding of the disclosure, the technical solutions in the embodiments of the disclosure will be described clearly and completely below with reference to the accompanying drawings in the embodiments of the disclosure. Obviously, the described embodiments are merely preferred embodiments of the present invention and are not limited to the embodiments described herein. On the contrary, these embodiments are provided so that the public will understand the disclosure more clearly and thoroughly.

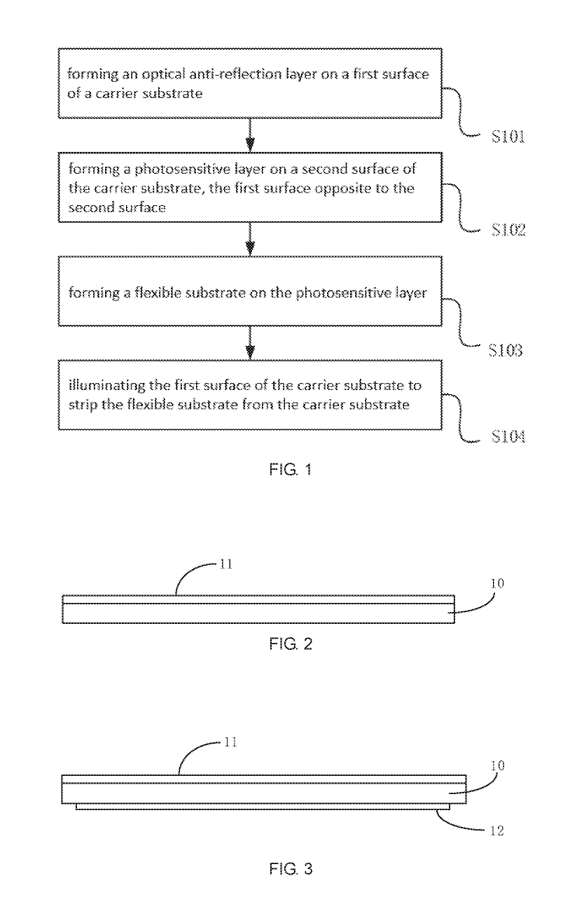

As shown in FIG. 1, FIG. 1 is a flow chart diagram of a stripping method for a flexible substrate according to an embodiment of the disclosure. The stripping method for a flexible substrate provided by this embodiment includes the following steps:

Step S101: forming an optical anti-reflection layer on a first surface of a carrier substrate.

Refer to FIG. 2, FIG. 2 is a structural schematic view of forming an optical anti-reflection layer on a first surface of a carrier substrate according to an embodiment of the disclosure. In this embodiment, an optical anti-reflection layer 11 is formed via performing physical vapor deposition, chemical liquid deposition or chemical vapor deposition on a first surface of a carrier substrate 10. The carrier substrate 10 may include a glass substrate, a material of the optical anti-reflection layer 11 is titanium oxide or magnesium fluoride. It should be noted that the carrier substrate 10 may be manufactured by other material with certain intensity and higher light transmittance, which is not limited herein. The material of the optical anti-reflection layer 11 is not limited to titanium oxide or magnesium fluoride, it may be other material capable of improving light transmittance, which is not limited herein.

Step S102: forming a photosensitive layer on a second surface of the carrier substrate, the first surface opposite to the second surface.

Refer to FIG. 3, FIG. 3 is a structural schematic view of forming a photosensitive layer on a second surface of a carrier substrate according to an embodiment of the disclosure. In this embodiment, a material of the photosensitive layer 12 is polyimide, and a thickness of the photosensitive layer 12 ranges from 1 μm to 10 μm. Wherein, the photosensitive layer 12 is disposed on the second surface of the carrier substrate 10, the optical anti-reflection layer 11 is disposed on the first surface of the carrier substrate 10, the first surface and the second surface are located on two opposite sides of the carrier substrate 10. It should be noted that the material of the photosensitive layer 12 is not limited to polyimide, and the thickness of the photosensitive layer 12 could be increased or decreased according to the actual situation, which are not limited herein.

Step S103: forming a flexible substrate on the photosensitive layer.

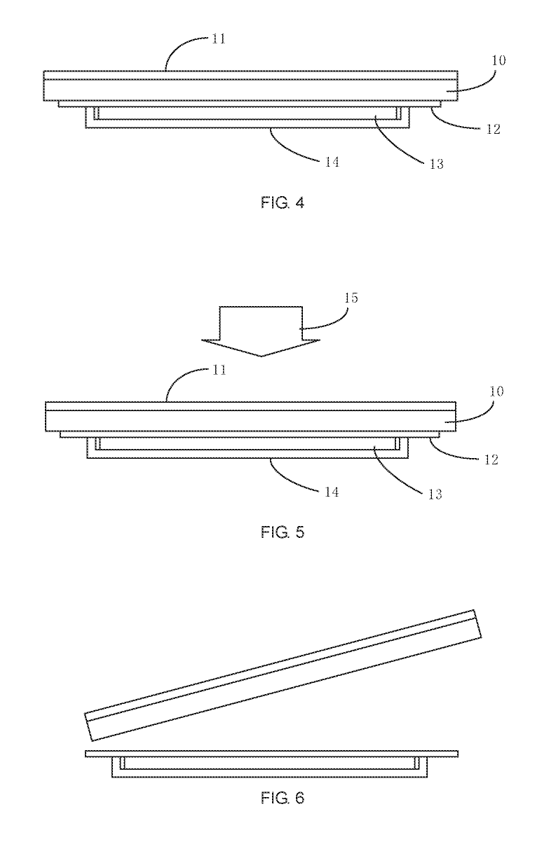

Refer to FIG. 4, FIG. 4 is a structural schematic view of forming a flexible substrate on a photosensitive layer according to an embodiment of the disclosure. In this embodiment, a thin film transistor layer (not shown in figure) is formed on a surface of the photosensitive layer 12, an OLED layer 13 is formed on a surface of the thin film transistor layer and an encapsulation layer 14 is formed on a surface of the OLED layer 13.

In this embodiment, after a metal film layer is deposited on the photosensitive layer 12, the metal film layer is etched to form a gate, then a gate insulating layer is deposited on a surface of the gate, wherein the gate insulating layer includes at least one of silicon nitride (SiNx) and silicon oxide (SiOx). After the gate, a source and a drain are formed, a passivation layer is deposited on the thin film transistor layer. A contact hole is disposed on the passivation layer, a contact electrode is disposed in the contact hole. The manufacturing method of the thin film transistor layer can also be other well-known methods, which are not limited herein.

In this embodiment, the OLED layer is formed by vapor depositing on the surface of the thin film transistor layer. It should be noted that the formation method of the OLED layer is not limited to vapor depositing, other existing formation method of the OLED layer also could be used such as ink jet printing, which is not limited herein.

In this embodiment, an encapsulation layer is formed by performing thin film encapsulation on the surface of the OLED layer. It should be noted that the formation method of the encapsulation layer is not limited to the thin film encapsulation, and other formation method of the encapsulation layer could be used such as ink jet printing, which is not limited herein.

Step S104: illuminating the first surface of the carrier substrate to strip the flexible substrate from the carrier substrate.

Refer to FIG. 5 and FIG. 6, FIG. 5 is a structural schematic view of illuminating a first surface of a carrier substrate according to an embodiment of the disclosure, FIG. 6 is a structural schematic view of stripping a flexible substrate from a carrier substrate according to an embodiment of the disclosure. In this embodiment, wherein illuminating the first surface of the carrier substrate is with a laser 15, a thickness of the optical anti-reflection layer 11 is an odd multiple of ¼ wavelength of the laser 15. In this embodiment, the photosensitive layer 12 of the interface between the flexible substrate and the carrier substrate 10 is illuminated and scanned from the first surface of the carrier substrate is with the laser 15, the short pulse laser burns the material of the surface of the photosensitive layer 12 in contact with the carrier substrate 10 to strip the flexible substrate from the carrier substrate 10.

The stripping method for a flexible substrate provided by the above-mentioned embodiments could apply to the manufacturing of a flexible substrate.

Compare with the conventional technology, a stripping method for a flexible substrate provided by the disclosure includes: forming an optical anti-reflection layer on a first surface of a carrier substrate; forming a photosensitive layer on a second surface of the carrier substrate, the first surface opposite to the second surface; forming a flexible substrate on the photosensitive layer; and illuminating the first surface of the carrier substrate to strip the flexible substrate from the carrier substrate. The optical anti-reflection layer of the disclosure can improve the transmissivity of the incident light and reduce the reflectivity of the incident light, so the light energy utilization rate could be improved. Furthermore, the laser damage is also reduced due to the reduce of the reflected light energy.

What is claimed is:

1. A stripping method for a flexible substrate, comprising:
performing physical vapor deposition, chemical liquid deposition or chemical vapor deposition on a first surface of a carrier substrate to form an optical anti-reflection layer;
forming a photosensitive layer on a second surface of the carrier substrate, the first surface opposite to the second surface;
forming a flexible substrate on the photosensitive layer; and
illuminating the first surface of the carrier substrate with a laser to strip the flexible substrate from the carrier substrate.

2. The stripping method for a flexible substrate according to claim 1, wherein a thickness of the optical anti-reflection layer is an odd multiple of ¼ wavelength of the laser.

3. The stripping method for a flexible substrate according to claim 1, wherein a material of the optical anti-reflection layer is titanium oxide or magnesium fluoride.

4. The stripping method for a flexible substrate according to claim 1, wherein a material of the photosensitive layer is polyimide, and a thickness of the photosensitive layer ranges from 1 μm to 10 μm.

5. The stripping method for a flexible substrate according to claim 1, wherein the step of forming a flexible substrate on the photosensitive layer specifically comprises:
forming a thin film transistor layer on a surface of the photosensitive layer;
forming an OLED layer on a surface of the thin film transistor layer; and
forming an encapsulation layer on a surface of the OLED layer.

6. The stripping method for a flexible substrate according to claim 5, wherein the step of forming an OLED layer on a surface of the thin film transistor layer specifically comprises: vapor depositing the OLED layer on the surface of the thin film transistor layer.

7. The stripping method for a flexible substrate according to claim 5, wherein the step of forming an encapsulation layer on a surface of the OLED layer specifically comprises: performing thin film encapsulation on the surface of the OLED layer to form the encapsulation layer.

8. A stripping method for a flexible substrate, comprising:
forming an optical anti-reflection layer on a first surface of a carrier substrate;
forming a photosensitive layer on a second surface of the carrier substrate, the first surface opposite to the second surface;
forming a flexible substrate on the photosensitive layer; and
illuminating the first surface of the carrier substrate to strip the flexible substrate from the carrier substrate.

9. The stripping method for a flexible substrate according to claim 8, wherein the step of forming an optical anti-reflection layer on a first surface of a carrier substrate specifically comprises: performing physical vapor deposition, chemical liquid deposition or chemical vapor deposition on the first surface of the carrier substrate to form the optical anti-reflection layer.

10. The stripping method for a flexible substrate according to claim 8, wherein illuminating the first surface of the carrier substrate is with a laser.

11. The stripping method for a flexible substrate according to claim 10, wherein a thickness of the optical anti-reflection layer is an odd multiple of ¼ wavelength of the laser.

12. The stripping method for a flexible substrate according to claim 8, wherein a material of the optical anti-reflection layer is titanium oxide or magnesium fluoride.

13. The stripping method for a flexible substrate according to claim 8, wherein a material of the photosensitive layer is polyimide, and a thickness of the photosensitive layer ranges from 1 μm to 10 μm.

14. The stripping method for a flexible substrate according to claim 8, wherein the step of forming a flexible substrate on the photosensitive layer specifically comprises:
forming a thin film transistor layer on a surface of the photosensitive layer;
forming an OLED layer on a surface of the thin film transistor layer; and
forming an encapsulation layer on a surface of the OLED layer.

15. The stripping method for a flexible substrate according to claim 8, wherein the step of forming an OLED layer on a surface of the thin film transistor layer specifically comprises: vapor depositing the OLED layer on the surface of the thin film transistor layer.

16. The stripping method for a flexible substrate according to claim 14, wherein the step of forming an encapsulation layer on a surface of the OLED layer specifically comprises: performing thin film encapsulation on the surface of the OLED layer to form the encapsulation layer.

17. A flexible substrate, wherein the flexible substrate is manufactured by the following steps, comprising:
forming an optical anti-reflection layer on a first surface of a carrier substrate;
forming a photosensitive layer on a second surface of the carrier substrate, the first surface opposite to the second surface;
forming a flexible substrate on the photosensitive layer; and
illuminating the first surface of the carrier substrate to strip the flexible substrate from the carrier substrate.

18. The flexible substrate according to claim 17, wherein the step of forming an optical anti-reflection layer on a first surface of a carrier substrate specifically comprises: performing physical vapor deposition, chemical liquid deposition or chemical vapor deposition on the first surface of the carrier substrate to form the optical anti-reflection layer.

19. The flexible substrate according to claim 17, wherein a material of the optical anti-reflection layer is titanium oxide or magnesium fluoride.

20. The flexible substrate according to claim 17, wherein a material of the photosensitive layer is polyimide, and a thickness of the photosensitive layer ranges from 1 μm to 10 μm.
